(19) United States
(12) Patent Application Publication
(10) Pub. No.: US 2026/0183898 A1
(43) Pub. Date: Jul. 2, 2026

(54) FILM-THICKNESS DIFFERENCE ESTIMATING METHOD AND OPTICAL FILM-THICKNESS MEASURING APPARATUS

(71) Applicant: EBARA CORPORATION, Tokyo (JP)

(72) Inventors: Yuki WATANABE, Tokyo (JP); Yoichi SHIOKAWA, Tokyo (JP)

(21) Appl. No.: 19/423,829

(22) Filed: Dec. 17, 2025

(30) Foreign Application Priority Data
Dec. 24, 2024 (JP) 2024-227269

(51) Int. Cl. B24B 49/12; B24B 37/013; G01B 11/06; G06N 20/00; H10P 74/00; H10P 74/20

(52) U.S. Cl. CPC B24B 49/12; B24B 37/013; G01B 11/0625; G06N 20/00; H10P 74/203; H10P 74/238

(57) ABSTRACT

A method of estimating a film-thickness difference between multiple films constituting a workpiece during polishing of the workpiece is disclosed. The film-thickness difference estimating method includes: producing multiple measurement spectra of reflected light from the workpiece at the same polishing time while polishing the workpiece, the workpiece having a first film and a second film made of different materials; inputting each of the multiple measurement spectra into a classification model; outputting a classification result indicating that each of the multiple measurement spectra has been classified into either a first group or a second group from the classification model; inputting a measurement spectrum classified into the first group and a measurement spectrum classified into the second group into a film-thickness estimation model; outputting an estimated film thickness of the first film and an estimated film thickness of the second film of the workpiece at the polishing time from the film-thickness estimation model; and calculating an estimated film-thickness difference between the first film and the second film of the workpiece at the polishing time by subtracting the estimated film thickness of the second film from the estimated film thickness of the first film.

### CROSS REFERENCE TO RELATED APPLICATION

This document claims priority to Japanese Patent Application No. 2024-227269 filed Dec. 24, 2024, the entire contents of which are hereby incorporated by reference.

### BACKGROUND

In a manufacturing process of semiconductor devices, various materials are repeatedly formed in film shapes on a silicon wafer to form a multilayer structure. In order to form such a multilayer structure, a technique of planarizing a surface of an uppermost layer of the multilayer structure is becoming important. Chemical mechanical polishing (CMP) is used as one of such planarizing techniques.

The chemical mechanical polishing (CMP) is performed by a polishing apparatus. This type of polishing apparatus generally has a polishing table configured to support a polishing pad, a polishing head configured to hold a workpiece (e.g., a wafer having a film), and a polishing-liquid supply nozzle configured to supply a polishing liquid (e.g., slurry) onto the polishing pad. When the workpiece is to be polished, the surface of the workpiece is pressed against the polishing pad by the polishing head while the polishing liquid is supplied onto the polishing pad from the polishing-liquid supply nozzle. The polishing head and the polishing table are rotated individually to provide a relative movement between the workpiece and the polishing pad, so that a film forming the surface of the workpiece is polished.

The workpiece has a pattern forming an interconnect structure, and the surface of the workpiece has films made of different materials, such as dielectric films (e.g., an oxide films, a nitride film, etc.) and metal films (e.g., copper, tungsten, etc.). Polishing of the workpiece is terminated when a thickness of a film (e.g., a dielectric film, a metal film, etc.) constituting the surface of the workpiece has reached a predetermined target value. In order to measure the thickness of the film of the surface of the workpiece, the polishing apparatus generally includes an optical film-thickness measuring apparatus. This optical film-thickness measuring apparatus is configured to direct light, emitted by a light source, to the surface of the workpiece and analyze a spectrum of reflected light from the workpiece to determine the film thickness of the workpiece.

In polishing of the workpiece having multiple films made of different materials, a film-thickness difference (e.g., dishing) may occur between the multiple films due to a difference in polishing rate depending on the materials constituting the films, variations in film thickness before polishing of the workpiece, etc. Conventionally, this film-thickness difference is measured, after polishing of the workpiece, by a stand-alone type film-thickness measuring device with high measurement accuracy, and therefore it is difficult to measure the film-thickness difference during polishing of the workpiece.

### SUMMARY

Therefore, there are provided a method of estimating a film-thickness difference between multiple films constituting a workpiece, such as a wafer, during polishing of the workpiece, and an optical film-thickness measuring apparatus.

Embodiments, which will be described below, relate to a technique of polishing a workpiece, such as a wafer, a substrate, or a panel, for use in manufacturing of semiconductor devices, and more particularly to a technique of estimating a film-thickness difference in the workpiece using a film-thickness estimation model.

In an embodiment, there is provided a film-thickness difference estimating method comprising: producing multiple measurement spectra of reflected light from a workpiece at the same polishing time while polishing the workpiece, the workpiece having a first film and a second film made of different materials; inputting each of the multiple measurement spectra into a classification model, the classification model being constructed as a trained model by machine learning using classification training data including multiple sample spectra of reflected light from a sample having the first film and the second film and classification labels for the multiple sample spectra; outputting, from the classification model, a classification result indicating that each of the multiple measurement spectra has been classified into either a first group or a second group, the first group being a group to which a measurement spectrum of reflected light from the first film belongs, and the second group being a group to which a measurement spectrum of reflected light from the second film belongs; inputting the measurement spectrum of the reflected light from the first film, which has been classified into the first group, and the measurement spectrum of the reflected light from the second film, which has been classified into the second group, into a film-thickness estimation model, the film-thickness estimation model being constructed as a trained model by machine learning using film-thickness estimation training data including the multiple sample spectra and film thicknesses corresponding to the multiple sample spectra; outputting an estimated film thickness of the first film of the workpiece and an estimated film thickness of the second film of the workpiece at the polishing time from the film-thickness estimation model; and calculating an estimated film-thickness difference between the first film and the second film of the workpiece at the polishing time by subtracting the estimated film thickness of the second film from the estimated film thickness of the first film.

In an embodiment, inputting the measurement spectrum classified into the first group and the measurement spectrum classified into the second group into the film-thickness estimation model comprises inputting the measurement spectrum classified into the first group into a first film-thickness estimation model, and inputting the measurement spectrum classified into the second group into a second film-thickness estimation model, the first film-thickness estimation model is constructed as a trained model by machine learning using first film-thickness estimation training data including sample spectra belonging to the first group among the multiple sample spectra and film thicknesses corresponding to the sample spectra belonging to the first group, the second film-thickness estimation model is constructed as a trained model by machine learning using second film-thickness estimation training data including sample spectra belonging to the second group among the multiple sample spectra and film thicknesses corresponding to the sample spectra belonging to the second group, and outputting the estimated film thickness of the first film of the workpiece and the estimated film thickness of the second film of the workpiece at the polishing time from the film-thickness estimation model comprises outputting the estimated film thickness of the first film of the workpiece at the polishing time from the first film-thickness estimation model, and outputting the estimated film thickness of the second film of the workpiece at the polishing time from the second film-thickness estimation model.

In an embodiment, the film-thickness estimation training data further includes classification labels indicating groups to which the multiple sample spectra belong, and inputting the measurement spectrum classified into the first group and the measurement spectrum classified into the second group into the film-thickness estimation model comprises inputting the measurement spectrum classified into the first group and a classification label indicating the first group into the film-thickness estimation model, and inputting the measurement spectrum classified into the second group and a classification label indicating the second group into the film-thickness estimation model.

In an embodiment, the classification labels for the multiple sample spectra are obtained by performing clustering on the multiple sample spectra to classify the multiple sample spectra into the first group and the second group.

In an embodiment, the multiple sample spectra include a sample spectrum of reflected light from a boundary between the first film and the second film of the sample, outputting the classification result indicating that each of the multiple measurement spectra has been classified into either the first group or the second group from the classification model comprises outputting a classification result indicating that each of the multiple measurement spectra has been classified into either the first group, the second group, or a third group to which a measurement spectrum of reflected light from a boundary between the first film and the second film is classified from the classification model, and the film-thickness estimation training data includes sample spectra excluding a sample spectrum belonging to the third group from the multiple sample spectra, and film thicknesses corresponding to the sample spectra excluding the sample spectrum belonging to the third group from the multiple sample spectra.

In an embodiment, the classification labels for the multiple sample spectra are obtained by performing clustering on the multiple sample spectra to classify the multiple sample spectra into the first group, the second group, and the third group.

In an embodiment, the first film comprises a dielectric film, the second film comprises a metal film, and the film-thickness difference estimating method further comprises: outputting a polishing end signal to terminate polishing of the workpiece when the estimated film-thickness difference exceeds a predetermined acceptable value.

In an embodiment, the first film comprises a metal film, the second film comprises a dielectric film, and the film-thickness difference estimating method further comprises: outputting a polishing continuation signal to continue polishing of the workpiece when the estimated film-thickness difference is equal to or larger than a predetermined threshold value and after a polishing end point of the workpiece.

In an embodiment, there is provided an optical film-thickness measuring apparatus comprising: a light source configured to emit light; an optical sensor head configured to direct the light emitted from the light source to a workpiece and receive reflected light from the workpiece, the workpiece having a first film and a second film made of different materials; and a processing system configured to produce a spectrum of the reflected light, wherein the processing system is configured to: produce multiple measurement spectra of reflected light from a workpiece at the same polishing time during polishing of the workpiece; input each of the multiple measurement spectra into a classification model, the classification model being constructed as a trained model by machine learning using classification training data including multiple sample spectra of reflected light from a sample having the first film and the second film and classification labels for the multiple sample spectra; output, from the classification model, a classification result indicating that each of the multiple measurement spectra has been classified into either a first group or a second group, the first group being a group to which a measurement spectrum of reflected light from the first film belongs, and the second group being a group to which a measurement spectrum of reflected light from the second film belongs; input the measurement spectrum of the reflected light from the first film, which has been classified into the first group, and the measurement spectrum of the reflected light from the second film, which has been classified into the second group, into a film-thickness estimation model, the film-thickness estimation model being constructed as a trained model by machine learning using film-thickness estimation training data including the multiple sample spectra and film thicknesses corresponding to the multiple sample spectra; output an estimated film thickness of the first film of the workpiece and an estimated film thickness of the second film of the workpiece at the polishing time from the film-thickness estimation model; and calculate an estimated film-thickness difference between the first film and the second film of the workpiece at the polishing time by subtracting the estimated film thickness of the second film from the estimated film thickness of the first film.

In an embodiment, the processing system is configured to: input the measurement spectrum classified into the first group into a first film-thickness estimation model, and input the measurement spectrum classified into the second group into a second film-thickness estimation model; and output the estimated film thickness of the first film of the workpiece at the polishing time from the first film-thickness estimation model, and output the estimated film thickness of the second film of the workpiece at the polishing time from the second film-thickness estimation model, the first film-thickness estimation model is constructed as a trained model by machine learning using first film-thickness estimation training data including sample spectra belonging to the first group among the multiple sample spectra and film thicknesses corresponding to the sample spectra belonging to the first group, and the second film-thickness estimation model is constructed as a trained model by machine learning using second film-thickness estimation training data including sample spectra belonging to the second group among the multiple sample spectra and film thicknesses corresponding to the sample spectra belonging to the second group.

In an embodiment, the film-thickness estimation training data further includes classification labels indicating groups to which the multiple sample spectra belong, and the processing system is configured to input the measurement spectrum classified into the first group and a classification label indicating the first group into the film-thickness estimation model, and input the measurement spectrum classified into the second group and a classification label indicating the second group into the film-thickness estimation model.

In an embodiment, the classification labels for the multiple sample spectra are obtained by performing clustering on the multiple sample spectra to classify the multiple sample spectra into the first group and the second group.

In an embodiment, the multiple sample spectra include a sample spectrum of reflected light from a boundary between the first film and the second film of the sample, the processing system is configured to output a classification result indicating that each of the multiple measurement spectra has been classified into either the first group, the second group, or a third group to which a measurement spectrum of reflected light from a boundary between the first film and the second film is classified from the classification model, and the film-thickness estimation training data includes sample spectra excluding a sample spectrum belonging to the third group from the multiple sample spectra, and film thicknesses corresponding to the sample spectra excluding the sample spectrum belonging to the third group from the multiple sample spectra.

In an embodiment, the classification labels for the multiple sample spectra are obtained by performing clustering on the multiple sample spectra to classify the multiple sample spectra into the first group, the second group, and the third group.

In an embodiment, the first film comprises a dielectric film, the second film comprises a metal film, and the processing system is configured to output a polishing end signal to terminate polishing of the workpiece when the estimated film-thickness difference exceeds a predetermined acceptable value.

In an embodiment, the first film comprises a metal film, the second film comprises a dielectric film, and the processing system is configured to output a polishing continuation signal to continue polishing of the workpiece when the estimated film-thickness difference is equal to or larger than a predetermined threshold value and after a polishing end point of the workpiece.

According to the above-described embodiments, during polishing of the workpiece, the multiple measurement spectra of the reflected light from the workpiece are classified, by using the classification model, into the first group to which the measurement spectrum of the reflected light from the first film belongs and the second group to which the measurement spectrum of the reflected light from the second film belongs. Furthermore, the estimated film thicknesses of the first film and the second film of the workpiece are obtained based on the measurement spectrum classified into the first group and the measurement spectrum classified into the second group by using the film-thickness estimation model. Therefore, the estimated film-thickness difference between the first film and the second film of the workpiece can be calculated.

### BRIEF DESCRIPTION OF THE DRAWINGS

FIG. 1 is a schematic diagram showing an embodiment of a polishing apparatus;

FIG. 2 is a diagram showing an example of a spectrum produced by a processing system;

FIG. 3 is a cross-sectional view showing an embodiment of detailed configurations of the polishing apparatus shown in FIG. 1;

FIG. 4 is a schematic diagram illustrating a principle of an optical film-thickness measuring apparatus;

FIG. 5 is a plan view showing a positional relationship between a workpiece and a polishing table;

FIG. 6 is a schematic diagram showing an example of changes in film thicknesses of a first film and a second film of the workpiece before and after polishing;

FIG. 7 is a diagram illustrating an embodiment of obtaining of classification labels for multiple sample spectra for use in producing of a classification model;

FIG. 8 is a diagram illustrating an embodiment of producing of the classification model;

FIG. 9 is a graph showing an example of a relationship between a film thickness of a first film of a sample and polishing time, and a relationship between a film thickness of a second film of the sample and polishing time;

FIG. 10 is a diagram illustrating an embodiment of producing of a film-thickness estimation model;

FIG. 11 is a diagram illustrating an embodiment of classification of multiple measurement spectra using the classification model;

FIG. 12 is a diagram illustrating an embodiment of estimation of the film thicknesses of the first film and the second film of the workpiece using the film-thickness estimation model;

FIG. 13 is a flowchart illustrating an embodiment of a method of estimating a film-thickness difference between the first film and the second film of the workpiece during polishing of the workpiece;

FIG. 14 is a diagram illustrating another embodiment of the producing of the film-thickness estimation model;

FIG. 15 is a diagram illustrating an embodiment of estimation of the film thicknesses of the first film and the second film of the workpiece using the film-thickness estimation model shown in FIG. 14;

FIG. 16 is a flowchart illustrating an embodiment of a method of estimating the film-thickness difference between the first film and the second film of the workpiece during polishing of the workpiece using the film-thickness estimation model shown in FIGS. 14 and 15;

FIG. 17 is a diagram illustrating another embodiment of the obtaining of the classification labels for the multiple sample spectra for use in producing of the classification model;

FIG. 18 is a diagram illustrating an embodiment of producing of the classification model using classification training data including the classification labels shown in FIG. 17; and

FIG. 19 is a diagram illustrating an embodiment of classification of the multiple measurement spectra using the classification model shown in FIG. 18.

### DESCRIPTION OF EMBODIMENTS

Embodiments will be described below with reference to the drawings.

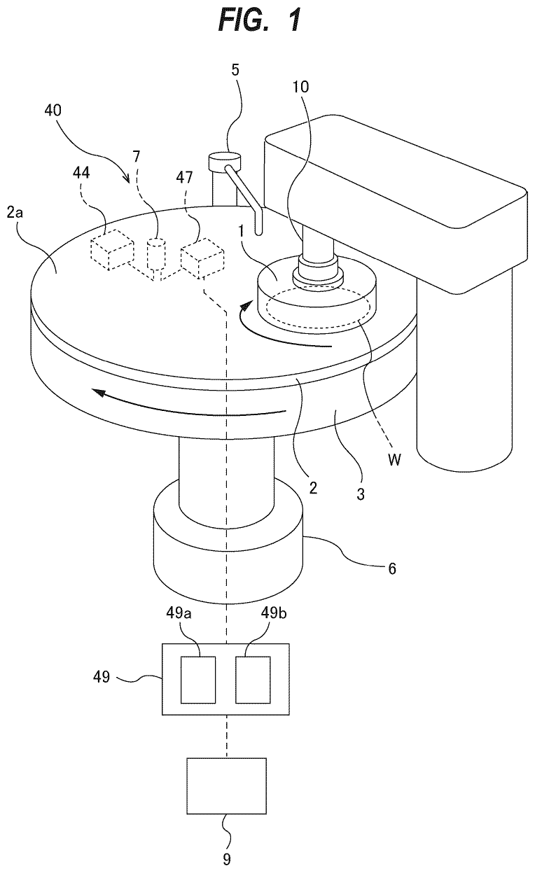

FIG. 1 is a schematic diagram showing an embodiment of a polishing apparatus. As shown in FIG. 1, the polishing apparatus includes a polishing table 3 configured to support a polishing pad 2, a polishing head 1 configured to press a workpiece W, such as a wafer for use in manufacturing of semiconductor device, against the polishing pad 2 on the polishing table 3, a table motor 6 configured to rotate the polishing table 3, and a polishing-liquid supply nozzle 5 configured to supply a polishing liquid (e.g., slurry) onto the polishing pad 2. The polishing pad 2 has an upper surface constituting a polishing surface 2a for polishing the workpiece W.

The polishing head 1 is coupled to a head shaft 10, which is coupled to a polishing-head motor (now shown). The polishing-head motor is configured to rotate the polishing head 1 together with the head shaft 10 in a direction indicated by an arrow. The polishing table 3 is coupled to the table motor 6, which is configured to rotate the polishing table 3 and the polishing pad 2 in a direction indicated by an arrow.

Polishing of the workpiece W is performed as follows. The polishing-liquid supply nozzle 5 supplies the polishing liquid onto the polishing surface 2a of the polishing pad 2 on the polishing table 3, while the polishing table 3 and the polishing head 1 are rotated in the directions indicated by the arrows in FIG. 1. While the workpiece W is being rotated by the polishing head 1, the workpiece W is pressed by the polishing head 1 against the polishing surface 2a of the polishing pad 2 in the presence of the polishing liquid on the polishing pad 2. A surface of the workpiece W is polished by a chemical action of the polishing liquid and a mechanical action of abrasive grains contained in the polishing liquid and/or the polishing pad 2.

The polishing apparatus includes an optical film-thickness measuring apparatus 40 configured to determine a film thickness of the workpiece W. The optical film-thickness measuring apparatus 40 includes a light source 44 configured to emit light, a spectrometer 47, an optical sensor head 7 coupled to the light source 44 and the spectrometer 47, and a processing system 49 coupled to the spectrometer 47. The optical sensor head 7, the light source 44, and the spectrometer 47 are secured to the polishing table 3, and rotate together with the polishing table 3 and the polishing pad 2. The position of the optical sensor head 7 is such that the optical sensor head 7 sweeps across the surface of the workpiece W on the polishing pad 2 each time the polishing table 3 and the polishing pad 2 make one rotation.

The processing system 49 includes a memory 49a storing programs therein for producing a spectrum, producing various models (e.g., a classification model, a film-thickness estimation model), and estimating a film-thickness difference in the surface of the workpiece W, which will be described later, and an arithmetic device 49b configured to perform arithmetic operations according to instructions contained in the programs. The processing system 49 is composed of at least one computer. The memory 49a includes a main memory, such as RAM, and an auxiliary memory, such as a hard disk drive (HDD) or a solid-state drive (SSD). Examples of the arithmetic device 49b include a CPU (central processing unit) and a GPU (graphic processing unit). However, the specific configurations of the processing system 49 are not limited to these examples.

The processing system 49 is composed of at least one computer. The at least one computer may be one server or a plurality of servers. The processing system 49 may be an edge server coupled to the spectrometer 47 by a communication line, or may be a cloud server or a fog server coupled to the spectrometer 47 by a communication network, such as the Internet or a local area network. The processing system 49 may be arranged in a gateway, a router, or the like.

The processing system 49 may be a plurality of servers coupled by a communication network, such as the Internet or a local area network. For example, the processing system 49 may be a combination of an edge server and a cloud server. In one embodiment, the memory 49a may be provided in a server (not shown) located away from the arithmetic device 49b.

The light source 44 is electrically coupled to the processing system 49 and emits the light upon receiving a trigger signal sent from the processing system 49. More specifically, while the optical sensor head 7 sweeps across the surface of the workpiece W on the polishing pad 2, the light source 44 receives multiple trigger signals and emits the light multiple times. Therefore, multiple measurement points on the workpiece W are irradiated with the light each time the polishing table 3 makes one revolution. The light emitted by the light source 44 is transmitted to the optical sensor head 7 and is directed from the optical sensor head 7 to the surface of the workpiece W. The light reflects off the surface of the workpiece W, and the reflected light from the surface of the workpiece Wis received by the optical sensor head 7 and transmitted to the spectrometer 47. The spectrometer 47 decomposes the reflected light according to wavelengths and measures the intensity of the reflected light at each of the wavelengths. The intensity measurement data of the reflected light is sent to the processing system 49.

The processing system 49 is configured to produce a spectrum of the reflected light from the intensity measurement data of the reflected light. The spectrum of the reflected light is expressed as a line graph (i.e., a spectral waveform) showing a relationship between the wavelength and the intensity of the reflected light. The intensity of the reflected light can be expressed as a relative value, such as reflectance or relative reflectance.

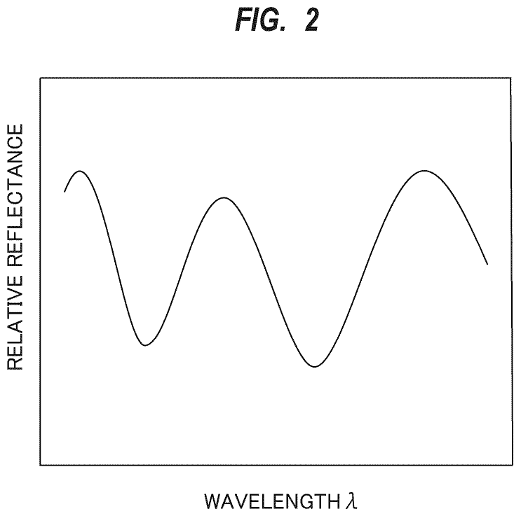

FIG. 2 is a diagram showing an example of a spectrum created by the processing system 49. The spectrum is represented as a line graph (i.e., a spectral waveform) showing the relationship between the wavelength and intensity of light. In FIG. 2, horizontal axis represents wavelength of the light reflected from the workpiece, and vertical axis represents relative reflectance derived from the intensity of the reflected light. The relative reflectance is an index value that represents the intensity of the reflected light. Specifically, the relative reflectance is a ratio of the intensity of the light to a predetermined reference intensity. By dividing the intensity of the light (i.e., the actually measured intensity) at each wavelength by a predetermined reference intensity, unwanted noises, such as a variation in the intensity inherent in an optical system or the light source of the apparatus, are removed from the actually measured intensity.

The reference intensity is an intensity that has been measured in advance at each of the wavelengths. The relative reflectance is calculated at each of the wavelengths. Specifically, the relative reflectance is determined by dividing the intensity of the light (the actually measured intensity) at each wavelength by the corresponding reference intensity. The reference intensity is, for example, obtained by directly measuring the intensity of light emitted from the optical sensor head 7, or by irradiating a mirror with light from the optical sensor head 7 and measuring the intensity of reflected light from the mirror. Alternatively, the reference intensity may be an intensity of the reflected light which is measured by the spectrometer 47 when a silicon substrate (bare substrate) with no film thereon is being water-polished in the presence of water on the polishing pad 2, or when the silicon substrate (bare substrate) is placed on the polishing pad 2.

In the actual polishing process, a dark level (which is a background intensity obtained under the condition that light is cut off) is subtracted from the actually measured intensity to determine a corrected actually measured intensity. Further, the dark level is subtracted from the reference intensity to determine a corrected reference intensity. Then the relative reflectance is calculated by dividing the corrected actually measured intensity by the corrected reference intensity. Specifically, the relative reflectance R(λ) can be calculated by using the following formula (1)

$$R ( λ ) = \frac{E ( λ ) - D ( λ )}{B ( λ ) - D ( λ )} \qquad ( 1 )$$

where λ is wavelength, E(λ) is the intensity of the light reflected from the wafer at the wavelength λ, B(λ) is the reference intensity at the wavelength λ, and D(λ) is the background intensity (i.e., dark level) at the wavelength λ obtained under the condition that light is cut off.

Each time the polishing table 3 makes one revolution, the optical sensor head 7 directs the light to the multiple measurement points on the workpiece W and receives the reflected light from the multiple measurement points. The multiple measurement points on the workpiece W include a central point of the workpiece W. The reflected light is transmitted to the spectrometer 47. The spectrometer 47 decomposes the reflected light according to its wavelengths and measures the intensity of the reflected light at each of the wavelengths. The intensity measurement data of the reflected light is sent to the processing system 49. In the example shown in FIG. 2, the spectrum of the reflected light is a spectral waveform showing the relationship between the relative reflectance and the wavelength of the reflected light. The spectrum of the reflected light may be a spectral waveform showing a relationship between the intensity itself of the reflected light and the wavelength of the reflected light.

Further, as will be described later, the processing system 49 receives the intensity measurement data of the reflected light returned from the multiple measurement points while the polishing table 3 makes one revolution, and produces multiple spectra from the intensity measurement data. The processing system 49 is configured to estimate (or determine) the film thickness of the workpiece W from each spectrum. In this specification, the multiple spectra obtained while the polishing table 3 makes one revolution are defined as multiple spectra of the reflected light from the multiple measurement points at the same polishing time.

As shown in FIG. 1, the processing system 49 is coupled to a polishing controller 9 for controlling a polishing operation for the workpiece W. The polishing controller 9 is configured to control the polishing operation for the workpiece W based on the film thickness of the workpiece W determined by the processing system 49. For example, the polishing controller 9 is configured to determine a polishing end point at which the film thickness of the workpiece W reaches a target film thickness, or change polishing conditions of the workpiece W when the film thickness of the workpiece W reaches a predetermined value.

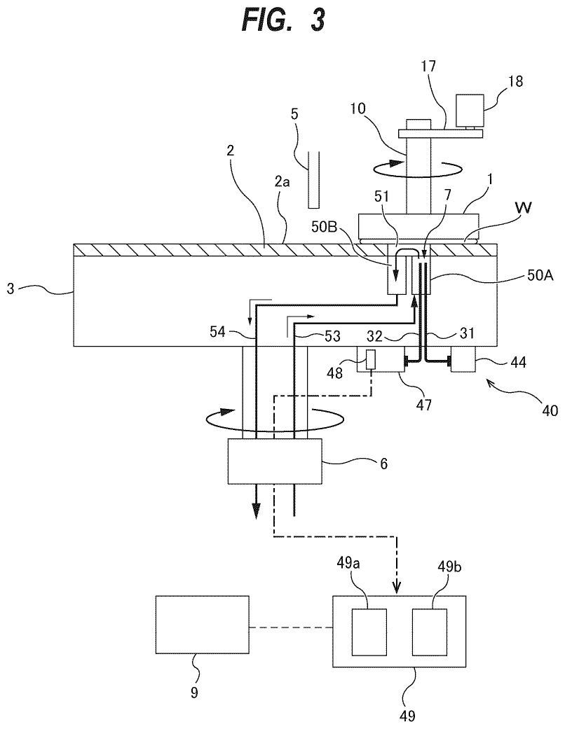

FIG. 3 is a cross-sectional view showing an embodiment of detailed configurations of the polishing apparatus shown in FIG. 1. The head shaft 10 is coupled to a polishing-head motor 18 via a coupling device 17, such as belt, so that the head shaft 10 is rotated by the polishing-head motor 18. This rotation of the head shaft 10 is transmitted to the polishing head 1 to rotate the polishing head 1 in the direction indicated by the arrow.

The spectrometer 47 includes a light detector 48. In one embodiment, the light detector 48 is constituted by photodiode, CCD, or CMOS. The optical sensor head 7 is optically coupled to the light source 44 and the light detector 48. The light detector 48 is electrically coupled to the processing system 49.

The optical film-thickness measuring apparatus 40 includes a light-emitting optical fiber cable 31 arranged to direct the light, emitted by the light source 44, to the surface of the workpiece W, and a light-receiving optical fiber cable 32 arranged to receive the reflected light from the workpiece W and transmit the reflected light to the spectrometer 47. An end of the light-emitting optical fiber cable 31 and an end of the light-receiving optical fiber cable 32 are located in the polishing table 3.

The end of the light-emitting optical fiber cable 31 and the end of the light-receiving optical fiber cable 32 constitute the optical sensor head 7 that directs the light to the surface of the workpiece W and receives the reflected light from the workpiece W. The other end of the light-emitting optical fiber cable 31 is coupled to the light source 44, and the other end of the light-receiving optical fiber cable 32 is coupled to the spectrometer 47. The spectrometer 47 is configured to decompose the reflected light from the workpiece W according to wavelengths and measure intensities of the reflected light over a predetermined wavelength range.

The light source 44 transmits the light to the optical sensor head 7 through the light-emitting optical fiber cable 31, and the optical sensor head 7 emits the light to the workpiece W. The reflected light from the workpiece W is received by the optical sensor head 7 and transmitted to the spectrometer 47 through the light-receiving optical fiber cable 32. The spectrometer 47 decomposes the reflected light according to its wavelengths and measures the intensity of the reflected light at each of the wavelengths. The spectrometer 47 sends the intensity measurement data of the reflected light to the processing system 49. The processing system 49 produces the spectrum of the reflected light from the intensity measurement data of the reflected light.

The polishing table 3 has a first hole 50A and a second hole 50B which open in an upper surface of the polishing table 3. The polishing pad 2 has a through-hole 51 arranged at a position corresponding to the holes 50A and 50B. The holes 50A and 50B are in fluid communication with the through-hole 51, which opens in the polishing surface 2a. The first hole 50A is coupled to a liquid supply line 53. The second hole 50B is coupled to a drain line 54. The optical sensor head 7, constituted of the end of the light-emitting optical fiber cable 31 and the end of the light-receiving optical fiber cable 32, is located in the first hole 50A, and is located below the through-hole 51.

During the polishing of the workpiece W, pure water as a rinsing liquid is supplied into the first hole 50A through the liquid supply line 53, and further supplied into the through-hole 51 through the first hole 50A. The pure water fills a space between the surface (i.e., the surface to be polished) of the workpiece W and the optical sensor head 7. The pure water flows into the second hole 50B and is discharged through the drain line 54. The pure water flowing through the first hole 50A and the through-hole 51 prevents the polishing liquid from entering the first hole 50A, thereby ensuring an optical path.

The light-emitting optical fiber cable 31 is an optical transmission element for transmitting the light, emitted by the light source 44, to the surface of the workpiece W. The distal ends of the light-emitting optical fiber cable 31 and the light-receiving optical fiber cable 32 are arranged in the first hole 50A, and are located near the surface, to be polished, of the workpiece W. The optical sensor head 7, composed of the distal end of the light-emitting optical fiber cable 31 and the distal end of the light-receiving optical fiber cable 32, is arranged so as to face the workpiece W held by the polishing head 1, so that predetermined multiple measurement points of the workpiece W are irradiated with the light each time the polishing table 3 makes one revolution. Only one optical sensor head 7 is provided in the polishing table 3 in this embodiment, while a plurality of optical sensor heads 7 may be provided in the polishing table 3.

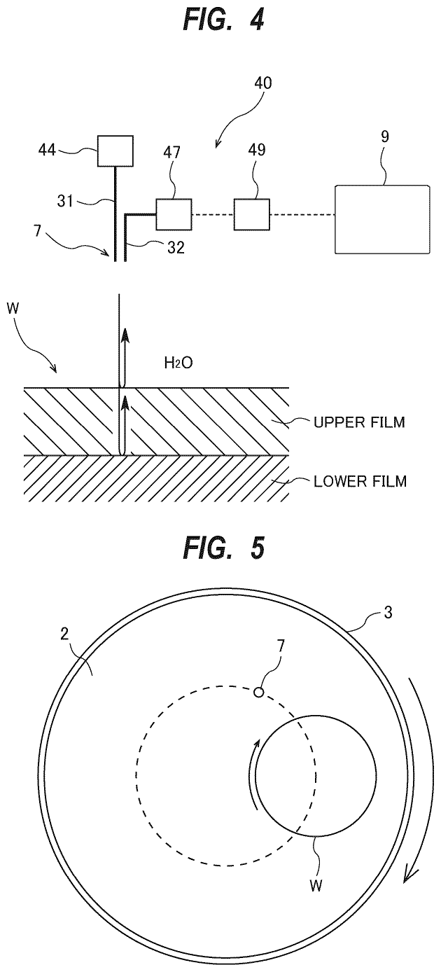

FIG. 4 is a schematic view illustrating a principle of the optical film-thickness measuring apparatus 40, and FIG. 5 is a plan view showing a positional relationship between the workpiece W and the polishing table 3. In this example shown in FIG. 4, the workpiece W has a lower film and an upper film formed on the lower film. The upper film is, for example, a dielectric film or a metal film. The optical sensor head 7, which is composed of the distal ends of the light-emitting optical fiber cable 31 and the light-receiving optical fiber cable 32, is oriented toward the surface of the workpiece W. The optical sensor head 7 is arranged so as to direct the light to multiple measurement points, including the center, of the workpiece W each time the polishing table 3 makes one revolution.

The light, which is cast on the workpiece W, is reflected off an interface between a medium (e.g., water in the example of FIG. 4) and the upper film and an interface between the upper film and the lower film. Light waves from these interfaces interfere with each other. The manner of interference between the light waves varies according to the thickness of the upper film (i.e., a length of an optical path). As a result, the spectrum, produced from the reflected light from the workpiece W, varies according to the thickness of the upper film. Furthermore, the shape of the spectrum, produced from the reflected light from the workpiece W, varies depending on the material constituting the upper film.

During polishing of the workpiece W, each time the polishing table 3 makes one revolution, the optical sensor head 7 sweeps across the workpiece W. While the optical sensor head 7 is located below the workpiece W, the light source 44 emits the light. The light is directed to the surface (i.e., the surface to be polished) of the workpiece W and the reflected light from the workpiece W is received by the optical sensor head 7 and is transmitted to the spectrometer 47. The spectrometer 47 measures the intensity of the reflected light at each of the wavelengths over the predetermined wavelength range and sends the intensity measurement data of the reflected light to the processing system 49. The processing system 49 produces, from the intensity measurement data, a spectrum of the reflected light indicating the light intensities at the respective wavelengths.

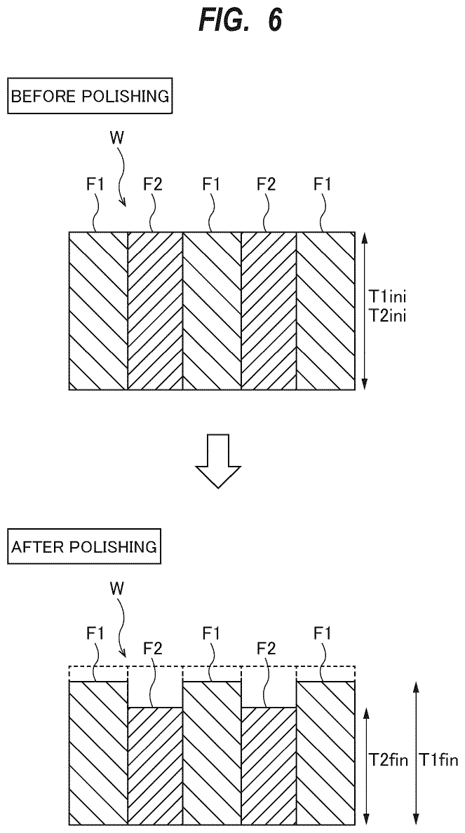

The workpiece W has a pattern forming an interconnect structure, and the surface of the workpiece W has multiple films made of different materials, such as dielectric films (e.g., an oxide film, a nitride film, etc.) and metal films (e.g., copper, tungsten, etc.). FIG. 6 is a schematic diagram showing an example of changes in film thicknesses of a first film F1 and a second film F2 of the workpiece W before and after polishing. In the example shown in FIG. 6, the workpiece W has the first film F1 and the second film F2 made of different materials on the surface of the workpiece W. Specifically, the upper film (see FIG. 4), which is the film to be polished on the workpiece W, is constituted of the first film F1 and the second film F2. For example, the first film F1 is an oxide film and the second film F2 is a metal film. However, the first film F1 and the second film F2 are not limited to this example. For example, the first film F1 may be an oxide film and the second film F2 may be a nitride film. The first film F1 and the second film F2 of this embodiment have film thicknesses that can be measured by the optical film-thickness measuring apparatus 40. The film thickness that can be measured by the optical film-thickness measuring apparatus 40 varies depending on the materials (i.e., types of the first film F1 and the second film F2) constituting the first film F1 and the second film F2. For example, in a case of a metal film, a film thickness of several hundred nanometers or less can be measured by the optical film-thickness measuring apparatus 40.

In the example shown in FIG. 6, a film thickness (i.e., an initial film thickness) T1ini of the first film F1 of the workpiece W before polishing is the same as a film thickness (i.e., an initial film thickness) T2ini of the second film F2 of the workpiece W before polishing. A film thickness (i.e., a final film thickness) T1fin of the first film F1 of the workpiece W after polishing is larger than a film thickness (i.e., a final film thickness) T2fin of the second film F2 of the workpiece W after polishing. In other words, after polishing of the workpiece W, a film-thickness difference T1fin-T2fin arises between the first film F1 and the second film F2. In the polishing of the workpiece W, this film-thickness difference T1fin−T2fin is required to be within an acceptable value. However, during the polishing of the workpiece W, it is difficult to identify the first film F1 and the second film F2 and measure the film thicknesses of the first film F1 and the second film F2 using the optical film-thickness measuring apparatus 40.

Thus, the optical film-thickness measuring apparatus 40 of this embodiment is configured to classify, during polishing of the workpiece W, the multiple spectra of the reflected light from the multiple measurement points on the workpiece W into a first group to which spectra of reflected light from the first film F1 belong and a second group to which spectra of reflected light from the second film F2 belong by using a classification model constructed by machine learning. Furthermore, the optical film-thickness measuring apparatus 40 is configured to estimate, during polishing of the workpiece W, film thicknesses of the first film F1 and the second film F2 from the multiple spectra of the reflected light classified into the first group and the second group by using a film-thickness estimation model constructed by machine learning. The optical film-thickness measuring apparatus 40 is configured to calculate a film-thickness difference between the first film F1 and the second film F2.

Producing of the classification model performed by the processing system 49 of the optical film-thickness measuring apparatus 40 will now be described. In the producing of the classification model, a sample of the same type as the workpiece W is used. For example, if the workpiece W is a wafer, a sample to be used is also a wafer. In another example, if the workpiece W is a panel, a sample to be used is also a panel.

Like the workpiece W, the sample has a first film F1 and a second film F2 on its surface. The sample is polished by the polishing apparatus shown in FIG. 1. During polishing of the sample, the processing system 49 produces multiple spectra of reflected light from the sample (hereinafter referred to as sample spectra). The producing of the sample spectra is performed in the same manner as the producing of the spectra of the reflected light from the workpiece W described with reference to FIGS. 1 to 5. Specifically, each time the polishing table 3 makes one revolution, the light source 44 directs the light through the optical sensor head 7 to multiple measurement points on the sample on the polishing pad 2. The optical sensor head 7 receives reflected light from the sample, and then transmits the reflected light to the spectrometer 47. The spectrometer 47 decomposes the reflected light from the sample according to its wavelengths and measures an intensity of the reflected light at each of the wavelengths. The intensity measurement data of the reflected light is sent to the processing system 49. The processing system 49 produces the sample spectra of the reflected light from the intensity measurement data of the reflected light from the sample.

The multiple sample spectra include a spectrum (spectra) of reflected light from the first film F1 of the sample and a spectrum (spectra) of reflected light from the second film F2 of the sample. The multiple sample spectra are stored in the memory 49a of the processing system 49 together with polishing times at which the multiple sample spectra were obtained. Specifically, the multiple sample spectra are associated with the polishing times at which the multiple sample spectra were obtained, respectively, and are stored in the memory 49a. The multiple sample spectra are used as classification training data for producing the classification model and film-thickness estimation training data for producing the film-thickness estimation model. In order to improve the accuracies of the classification model and the film-thickness estimation model, it is preferable to prepare a large number of sample spectra as the classification training data and the film-thickness estimation training data. Therefore, the processing system 49 produces multiple sample spectra obtained during polishing of multiple samples and stores the multiple sample spectra in the memory 49a.

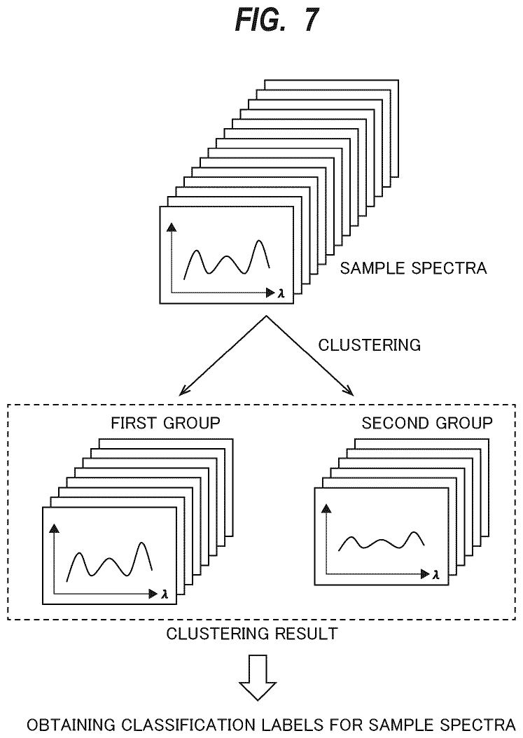

FIG. 7 is a diagram illustrating an embodiment of obtaining classification labels for the multiple sample spectra for use in producing of the classification model. As shown in FIG. 7, the processing system 49 is configured to perform clustering on the multiple sample spectra of the reflected light from the sample having the first film F1 and the second film F2 to classify the multiple sample spectra into a first group and a second group. This clustering is unsupervised machine learning. Examples of algorithm of the clustering include k-means, Gaussian Mixture Model (GMM), and DBSCAN. The arithmetic device 49b of the processing system 49 performs the clustering by performing arithmetic operations according to instructions included in the program.

More specifically, the processing system 49 performs labeling for multiple groups, which are the clustering result when the clustering is performed on the multiple sample spectra, as the first group to which the sample spectra of the reflected light from the first film F1 belong and the second group to which the sample spectra of the reflected light from the second film F2 belong. The labeling for the multiple groups may be performed based on an external input (e.g., an instruction from a user), may be performed based on a spectrum of reflected light from a film having a known film type, or may be performed based on a theoretical spectrum theoretically calculated from a film type.

The processing system 49 is configured to obtain classification labels indicating the groups to which the multiple sample spectra belong based on the clustering result. A classification label indicating the first group is associated with the sample spectra of the reflected light from the first film F1, and a classification label indicating the second group is associated with the sample spectra of the reflected light from the second film F2. The classification labels associated with the sample spectra are stored in the arithmetic device 49b of the processing system 49.

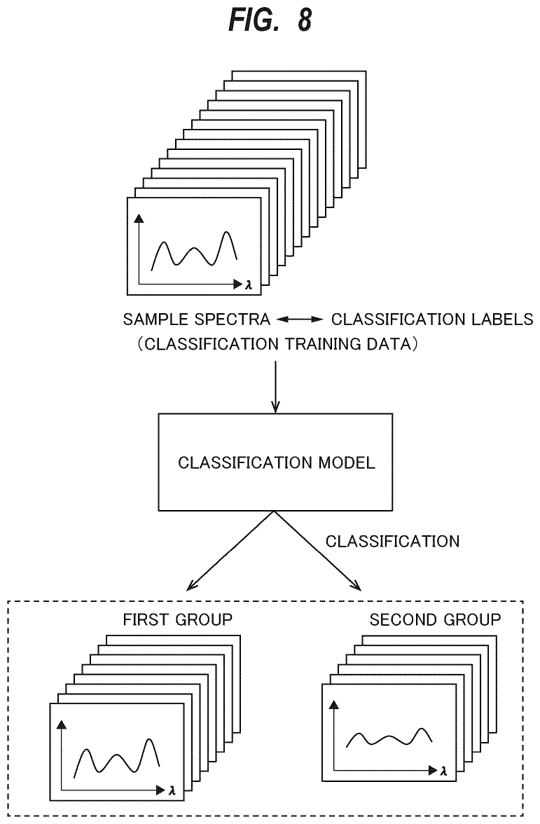

FIG. 8 is a diagram illustrating an embodiment of producing of the classification model. As shown in FIG. 8, the processing system 49 is configured to produce the classification model by performing machine learning using the classification training data including the multiple sample spectra and the classification labels for the multiple sample spectra. Examples of the machine learning algorithm include a support vector regression method, a deep learning method, a random forest method, and a decision tree method. In this embodiment, the deep learning method, which is an example of machine learning, is used. The deep learning method is a learning method based on a neural network having multiple intermediate layers (also referred to as hidden layers). In this specification, machine learning using a neural network containing an input layer, two or more intermediate layers, and an output layer is referred to as deep learning.

The classification model is composed of a neural network. The memory 49a of the processing system 49 stores a program for producing or constructing the classification model according to the machine learning algorithm. The arithmetic device 49b of the processing system 49 produces the classification model by performing arithmetic operations according to instructions included in the program. Producing the classification model by the machine learning involves optimizing parameters, such as weights, of the neural network.

In the producing of the classification model, the multiple sample spectra contained in the classification training data are used as explanatory variables, and the classification labels for the multiple sample spectra are used as objective variables (i.e., correct labels). Specifically, the processing system 49 inputs each sample spectrum to the input layer of the classification model, and adjusts the parameters (weights, biases, etc.) of the classification model such that the output layer of the classification model outputs a classification label indicating a group to which the input sample spectrum belongs.

As a result of such machine learning, the classification model as a trained model is constructed. The classification model is stored in the memory 49a of the processing system 49. By using the classification model produced in this manner, the spectra produced from the reflected light from the workpiece W can be classified into the first group and the second group during polishing of the workpiece W, as will be described later.

Next, producing of the film-thickness estimation model performed by the processing system 49 will be described. In producing of the film-thickness estimation model, the sample spectra used in the producing of the classification model described above and the film-thickness estimation training data including film thicknesses corresponding to the sample spectra are used. The film thicknesses corresponding to the sample spectra are determined based on a film thickness (i.e., an initial film thickness) of the first film F1 of the sample before polishing, a film thickness (i.e., a final film thickness) of the first film F1 of the sample after polishing, a film thickness (i.e., an initial film thickness) of the second film F2 of the sample before polishing, and a film thickness (i.e., a final film thickness) of the second film F2 of the sample after polishing.

The initial film thickness and the final film thickness of the first film F1 of the sample and the initial film thickness and the final film thickness of the second film F2 of the sample are measured by a film-thickness measuring device (not shown). This film-thickness measuring device is a so-called stand-alone type film-thickness measuring device, and is configured to be able to measure the first film F1 and the second film F2 of the sample with high accuracy. Therefore, the first film F1 and the second film F2 of the sample can be identified, and the film thicknesses of the first film F1 and the second film F2 can be measured. A configuration and a type of the film-thickness measuring device are not particularly limited. For example, the film-thickness measuring device may be an optical film-thickness measuring device configured to measure a film thickness of a sample in a stationary state. The film-thickness measuring device may be disposed outside the polishing apparatus. The initial film thickness and the final film thickness of the first film F1 of the sample and the initial film thickness and the final film thickness of the second film F2 measured by the film-thickness measuring device are stored in the memory 49a of the processing system 49.

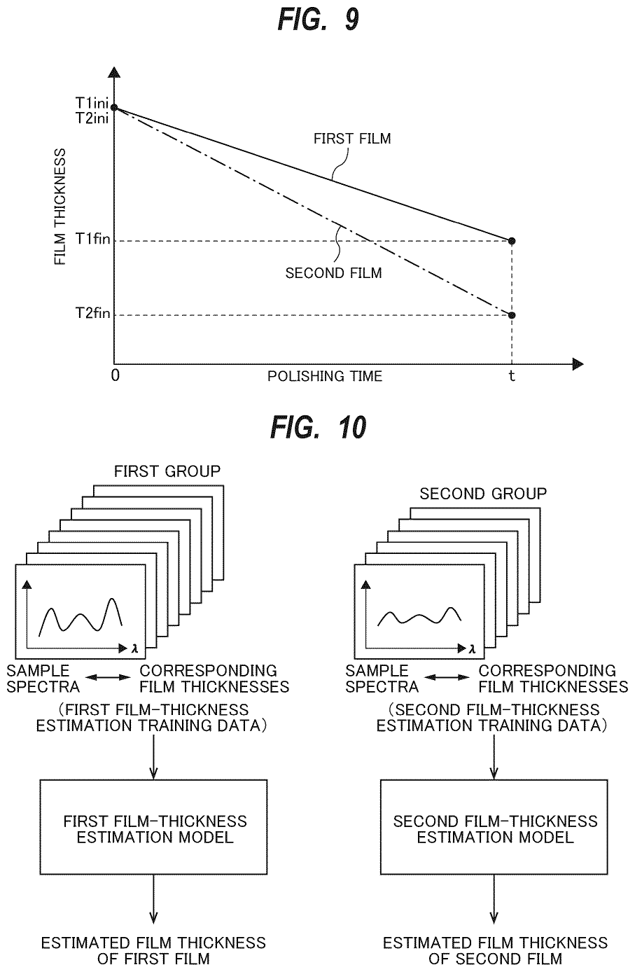

The sample is polished by the polishing apparatus at a constant polishing rate. The polishing rate is an amount of decrease in the thickness of the film per unit time, and is also called a removal rate. FIG. 9 is a graph showing an example of a relationship between the film thickness of the first film F1 of the sample and polishing time, and a relationship between the film thickness of the second film F2 of the sample and polishing time. When the polishing rate of the sample is constant, the film thickness of the first film F1 decreases linearly from an initial film thickness T1ini to a final film thickness T1fin with the polishing time, as shown by a solid line in FIG. 9. Furthermore, the film thickness of the second film F2 decreases linearly from an initial film thickness T2ini to a final film thickness T2fin with the polishing time, as shown by a dash-dot-dash line in FIG. 9. Therefore, film thicknesses between the initial film thickness T1ini and the final film thickness T1fin of the first film F1 and film thicknesses between the initial film thickness T2ini and the final film thickness T2fin of the second film F2 can be calculated by interpolation based on each polishing time.

The processing system 49 is configured to determine film thicknesses corresponding to the multiple sample spectra from the initial film thickness T1ini and the final film thickness T1fin of the first film F1 of the sample, the initial film thickness T2ini and the final film thickness T2fin of the second film F2, and the polishing times at which the multiple sample spectra were obtained (the polishing times associated with the multiple sample spectra). Specifically, the processing system 49 determines multiple film thicknesses corresponding to the multiple sample spectra belonging to the first group from the initial film thickness T1ini and the final film thickness T1fin of the first film F1 of the sample and the polishing times at which the multiple sample spectra were obtained. Similarly, the processing system 49 determines multiple film thicknesses corresponding to the multiple sample spectra belonging to the second group from the initial film thickness T2ini and the final film thickness T2fin of the second film F2 of the sample and the polishing times at which the multiple sample spectra were obtained. The determined film thicknesses corresponding to the multiple sample spectra are associated with the multiple sample spectra, respectively, and are stored in the memory 49a.

FIG. 10 is a diagram illustrating an embodiment of producing the film-thickness estimation model. The processing system 49 is configured to produce the film-thickness estimation model by performing machine learning using the film-thickness estimation training data including the multiple sample spectra and the film thicknesses corresponding to the multiple sample spectra. As shown in FIG. 10, in this embodiment, the film-thickness estimation model includes a first film-thickness estimation model for estimating a film thickness of the first film F1 and a second film-thickness estimation model for estimating a film thickness of the second film F2. The processing system 49 produces the first film-thickness estimation model by performing machine learning using first film-thickness estimation training data including the sample spectra belonging to the first group among the multiple sample spectra and film thicknesses corresponding to the sample spectra belonging to the first group. Similarly, the processing system 49 produces the second film-thickness estimation model by performing machine learning using second film-thickness estimation training data including sample spectra belonging to the second group among the multiple sample spectra and film thicknesses corresponding to the sample spectra belonging to the second group.

Examples of the machine learning algorithm include a support vector regression method, a deep learning method, a random forest method, and a decision tree method. In this embodiment, the deep learning method, which is an example of machine learning, is used. The deep learning method is a learning method based on a neural network having multiple intermediate layers (also referred to as hidden layers). In this specification, machine learning using a neural network containing an input layer, two or more intermediate layers, and an output layer is referred to as deep learning.

The first film-thickness estimation model and the second film-thickness estimation model are each composed of a neural network. The memory 49a of the processing system 49 stores programs for producing or constructing the first film-thickness estimation model and the second film-thickness estimation model according to the machine learning algorithm. The arithmetic device 49b of the processing system 49 produces the first film-thickness estimation model and the second film-thickness estimation model by performing arithmetic operations according to instructions included in the programs. Producing the first film-thickness estimation model and the second film-thickness estimation model by the machine learning involves optimizing parameters, such as the weights, of the neural network.

In the producing of the first film-thickness estimation model and the second film-thickness estimation model, the multiple sample spectra contained in the first film-thickness estimation training data and the second film-thickness estimation training data are used as explanatory variables, and the film thicknesses corresponding to the multiple sample spectra are used as objective variables (i.e., correct labels). Specifically, the processing system 49 inputs each sample spectrum to the input layer of the first film-thickness estimation model and the second film-thickness estimation models, and adjusts the parameters (weights, biases, etc.) of the first film-thickness estimation model and the second film-thickness estimation model such that the output layer outputs film thicknesses corresponding to the input sample spectrum.

As a result of such machine learning, the first film-thickness estimation model and the second film-thickness estimation model as trained models are constructed. The first film-thickness estimation model and the second film-thickness estimation model are stored in the memory 49a of the processing system 49. By using the first film-thickness estimation model and the second film-thickness estimation model produced in this manner, estimated film thicknesses of the first film F1 and the second film F2 of the workpiece W can be obtained based on the spectra produced from the reflected light from the workpiece W during polishing of the workpiece W, as will be described later.

Next, calculation of the film-thickness difference between the first film F1 and the second film F2 of the workpiece W by the processing system 49 using the classification model and the film-thickness estimation model (in this embodiment, the first film-thickness estimation model and the second film-thickness estimation model) will be described. As described with reference to FIGS. 1 to 5, during polishing of the workpiece W, the processing system 49 produces the multiple spectra of the reflected light from the multiple measurement points on the workpiece W at the same polishing time while the polishing table 3 makes one revolution. In the following description, the spectrum of the reflected light from the workpiece W will be referred to as a measurement spectrum.

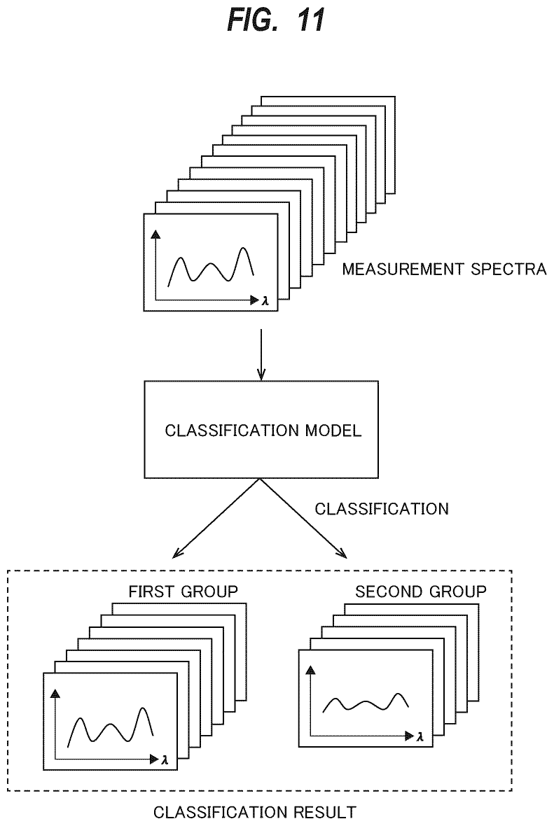

FIG. 11 is a diagram illustrating an embodiment of classification of the multiple measurement spectra using the classification model. As shown in FIG. 11, the processing system 49 is configured to input each of the multiple measurement spectra obtained at the same polishing time into the classification model that has been trained, and output, from the classification model, a classification result indicating that each of the multiple measurement spectra is classified into either the first group or the second group. Thus, the multiple measurement spectra produced during polishing of the workpiece W can be classified into the first group to which a measurement spectrum (spectra) of the reflected light from the first film F1 belongs and the second group to which a measurement spectrum (spectra) of the reflected light from the second film F2 belongs.

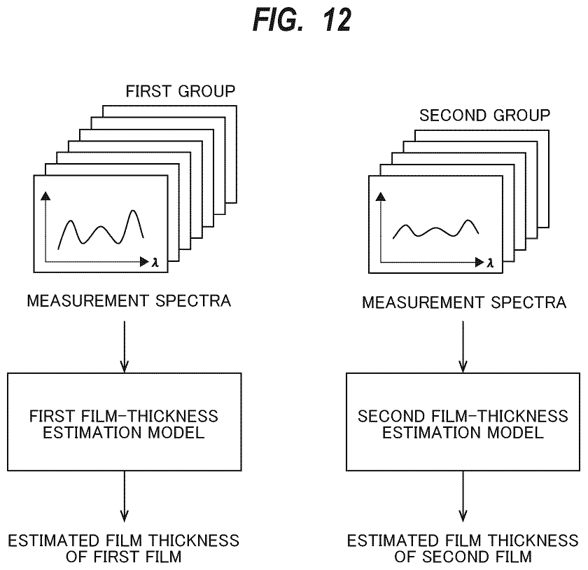

FIG. 12 is a diagram illustrating an embodiment of estimating the film thicknesses of the first film F1 and the second film F2 of the workpiece W using the film-thickness estimation model. The processing system 49 is configured to input the measurement spectrum of the reflected light from the first film F1 classified into the first group by the classification model and the measurement spectrum of the reflected light from the second film F2 classified into the second group into the film-thickness estimation model that has been trained, and output estimated film thicknesses of the first film F1 and the second film F2 of the workpiece W at the same polishing time from the film-thickness estimation model. As shown in FIG. 12, in this embodiment, the processing system 49 is configured to input the measurement spectrum of the reflected light from the first film F1, classified into the first group by the classification model, into the first film-thickness estimation model, and input the measurement spectrum of the reflected light from the second film F2, classified into the second group, into the second film-thickness estimation model. Furthermore, the processing system 49 is configured to output an estimated film thickness of the first film F1 of the workpiece W at the same polishing time from the first film-thickness estimation model, and output an estimated film thickness of the second film F2 of the workpiece W at the same polishing time from the second film-thickness estimation model.

When multiple measurement spectra among the multiple measurement spectra have been classified into the first group, the processing system 49 inputs each of the multiple measurement spectra classified into the first group into the first film-thickness estimation model to thereby output multiple estimated film thicknesses of the first film F1 of the workpiece W from the first film-thickness estimation model. In one embodiment, the processing system 49 may calculate an average value of the multiple estimated film thicknesses of the first film F1 output from the first film-thickness estimation model to determine the estimated film thickness of the first film F1 at the same polishing time. In another embodiment, the processing system 49 may calculate another representative value, such as a median value, of the multiple estimated film thicknesses of the first film F1 output from the first film-thickness estimation model to determine the estimated film thickness of the first film F1 at the same polishing time. In still another embodiment, the processing system 49 may determine one spectrum among the multiple measurement spectra classified into the first group as a representative measurement spectrum, input the representative measurement spectrum into the first film-thickness estimation model, and output the estimated film thickness of the first film F1 of the workpiece W from the first film-thickness estimation model.

Similarly, when multiple measurement spectra among the multiple measurement spectra have been classified into the second group, the processing system 49 inputs each of the multiple measurement spectra classified into the second group into the second film-thickness estimation model to thereby output multiple estimated film thicknesses of the second film F2 of the workpiece W from the second film-thickness estimation model. In one embodiment, the processing system 49 may calculate an average value of the multiple estimated film thicknesses of the second film F2 output from the second film-thickness estimation model to determine the estimated film thickness of the second film F2 at the same polishing time. In another embodiment, the processing system 49 may calculate another representative value, such as a median value, of the multiple estimated film thicknesses of the second film F2 output from the second film-thickness estimation model to determine the estimated film thickness of the second film F2 at the same polishing time. In still another embodiment, the processing system 49 may determine one spectrum among the multiple measurement spectra classified into the second group as a representative measurement spectrum, input the representative measurement spectrum into the second film-thickness estimation model, and output the estimated film thickness of the second film F2 of the workpiece W from the second film-thickness estimation model.

In this manner, the processing system 49 can obtain the estimated film thicknesses of the first film F1 and the second film F2 of the workpiece W at the same polishing time. The processing system 49 is configured to calculate an estimated film-thickness difference between the first film F1 and the second film F2 of the workpiece W at the same polishing time by subtracting the estimated film thickness of the second film F2 from the estimated film thickness of the first film F1 output from the film-thickness estimation model (in this embodiment, the first film-thickness estimation model and the second film-thickness estimation model). The processing system 49 can monitor the estimated film-thickness difference between the first film F1 and the second film F2 during polishing of the workpiece W by calculating the estimated film-thickness difference between the first film F1 and the second film F2 every time the polishing table 3 makes one revolution.

When either the first film F1 or the second film F2 is a metal film, it is required to prevent the metal film from being excessively polished relative to the other film, or from being under-polished relative to the other film. When the first film F1 is a dielectric film and the second film F2 is the metal film, the processing system 49 is configured to output a polishing end signal to terminate polishing of the workpiece W when the estimated film-thickness difference between the first film F1 and the second film F2 of the workpiece W exceeds a predetermined acceptable value. The polishing controller 9 is configured to terminate polishing of the workpiece W based on the polishing end signal from the processing system 49. In one embodiment, the processing system 49 may be configured to generate an alarm when the estimated film-thickness difference between the first film F1 and the second film F2 of the workpiece W exceeds the predetermined acceptable value. Therefore, the second film F2, which is the metal film, can be prevented from being over-polished relative to the first film F1, which is the dielectric film.

When the first film F1 is the metal film and the second film F2 is the dielectric film, the processing system 49 is configured to output a polishing continuation signal to continue polishing of the workpiece W when the estimated film-thickness difference between the first film F1 and the second film F2 of the workpiece W is equal to or larger than a predetermined threshold and after a polishing end point of the workpiece W. The polishing controller 9 is configured to continue polishing of the workpiece W based on the polishing continuation signal from the processing system 49. In one embodiment, during over-polishing of the workpiece W in which the workpiece W is further polished for a predetermined time after the polishing end point of the workpiece W, the polishing controller 9 may extend the predetermined time and continue the polishing (over-polishing) of the workpiece W based on the polishing continuation signal from the processing system 49. The first film F1, which is the metal film, can be prevented from being under-polished relative to the second film F2, which is the dielectric film.

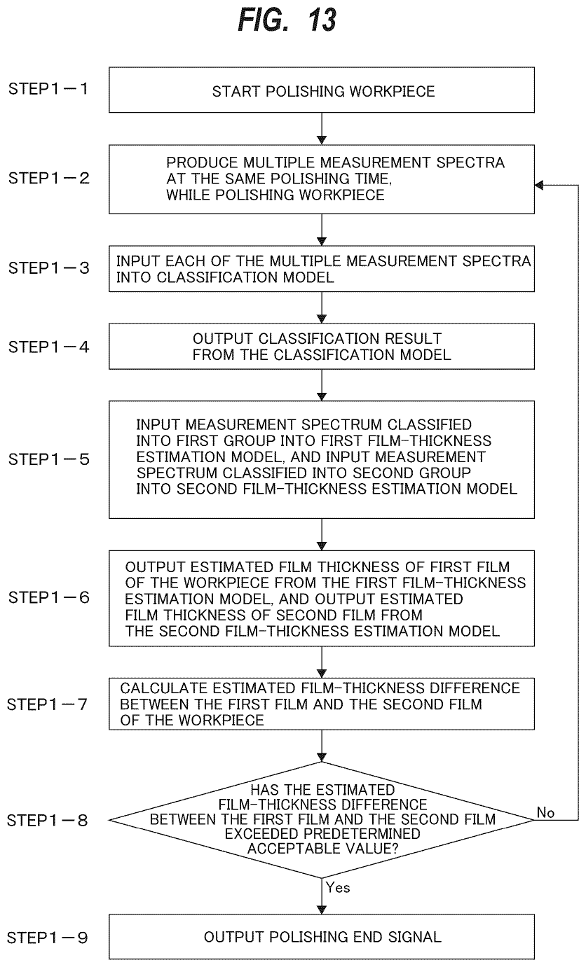

FIG. 13 is a flowchart showing an embodiment of a method of estimating the film-thickness difference between the first film F1 and the second film F2 of the workpiece W during polishing of the workpiece W. In this embodiment, the film-thickness difference between the first film F1 and the second film F2 of the workpiece W is estimated by the optical film-thickness measuring apparatus 40 described with reference to FIGS. 1 to 12.

In step 1-1, the workpiece W having the first film F1 and the second film F2 is transported to the polishing apparatus shown in FIG. 1, and the polishing apparatus starts polishing the workpiece W.

In step 1-2, during polishing of the workpiece W, the processing system 49 produces multiple measurement spectra of reflected light from multiple measurement points on the workpiece W at the same polishing time while the polishing table 3 makes one revolution.

In step 1-3, the processing system 49 inputs each of the multiple measurement spectra into the classification model (see FIG. 11). The classification model is a trained model constructed by machine learning using classification training data including multiple sample spectra of reflected light from the sample having the first film F1 and the second film F2 and classification labels for multiple sample spectra (see FIG. 8). The classification labels for the multiple sample spectra are obtained by performing clustering on the multiple sample spectra to classify the multiple sample spectra into a first group and a second group (see FIG. 7).

In step 1-4, the processing system 49 outputs a classification result indicating that each of the multiple measurement spectra has been classified into either the first group or the second group from the classification model (see FIG. 11). The first group is a group to which a measurement spectrum of reflected light from the first film F1 belongs, and the second group is a group to which a measurement spectrum of reflected light from the second film F2 belongs.

In step 1-5, the processing system 49 inputs the measurement spectrum of the reflected light from the first film F1 classified into the first group and the measurement spectrum of the reflected light from the second film F2 classified into the second group into the film-thickness estimation model (see FIG. 12). In this embodiment, the processing system 49 inputs the measurement spectrum of the reflected light from the first film F1 classified into the first group into the first film-thickness estimation model, and inputs the measurement spectrum of the reflected light from the second film F2 classified into the second group into the second film-thickness estimation model. The first film-thickness estimation model is a trained model constructed by machine learning using first film-thickness estimation training data including sample spectra belonging to the first group among the multiple sample spectra and film thicknesses corresponding to the sample spectra belonging to the first group. The second film-thickness estimation model is a trained model constructed by machine learning using second film-thickness estimation training data including sample spectra belonging to the second group among the multiple sample spectra and film thicknesses corresponding to the sample spectra belonging to the second group (see FIG. 10).

In step 1-6, the processing system 49 outputs, from the film-thickness estimation model (see FIG. 12), an estimated film thickness of the first film F1 and an estimated film thickness of the second film F2 of the workpiece W at the same polishing time. In this embodiment, the processing system 49 outputs, from the first film-thickness estimation model, the estimated film thickness of the first film F1 of the workpiece W at the same polishing time and outputs, from the second film-thickness estimation model, the estimated film thickness of the second film F2 of the workpiece W at the same polishing time.

In step 1-7, the processing system 49 calculates an estimated film-thickness difference between the first film F1 and the second film F2 of the workpiece W at the same polishing time by subtracting the estimated film thickness of the second film F2 from the estimated film thickness of the first film F1 output from the film-thickness estimation model (in this embodiment, the first film-thickness estimation model and the second film-thickness estimation model).

In the present embodiment, the first film F1 is a dielectric film, and the second film F2 is a metal film. In step 1-8, the processing system 49 determines whether the estimated film-thickness difference between the first film F1 and the second film F2 of the workpiece W that has been calculated exceeds a predetermined acceptable value. When the estimated film-thickness difference between the first film F1 and the second film F2 of the workpiece W exceeds the predetermined acceptable value (see “Yes” in the step 1-8), the processing system 49 outputs a polishing end signal to terminate polishing of the workpiece W (see step 1-9). The polishing controller 9 is configured to terminate polishing of the workpiece W based on the polishing end signal from the processing system 49. In one embodiment, the processing system 49 may generate an alarm when the estimated film-thickness difference between the first film F1 and the second film F2 of the workpiece W exceeds the predetermined acceptable value.

When the estimated film-thickness difference between the first film F1 and the second film F2 of the workpiece W is equal to or less than the predetermined acceptable value (see “No” in the step 1-8), the processing system 49 again produces multiple measurement spectra at the same polishing time (return to the step 1-2). In one embodiment, the processes of the steps 1-2 to 1-8 are repeated until a polishing end point is determined by the polishing controller 9.

In another embodiment, when the first film F1 is a metal film and the second film F2 is a dielectric film, the processing system 49 may output a polishing continuation signal to continue polishing of the workpiece W when the estimated film-thickness difference between the first film F1 and the second film F2 of the workpiece W is equal to or larger than a predetermined threshold and after the polishing end point of the workpiece W. In this case, the polishing controller 9 is configured to continue polishing of the workpiece W based on the polishing continuation signal from the processing system 49. In one embodiment, during over-polishing of the workpiece W, in which the workpiece W is further polished for a predetermined time after the polishing end point of the workpiece W, the polishing controller 9 may extend the predetermined time and continue the polishing (over-polishing) of the workpiece W based on the polishing continuation signal from the processing system 49.

According to this embodiment, during polishing of the workpiece W, the film thicknesses of the first film F1 and the second film F2 of the workpiece W can be estimated by using the classification model and the film-thickness estimation model, and the estimated film-thickness difference between the first film F1 and the second film F2 can be calculated. The processing system 49 calculates the estimated film-thickness difference between the first film F1 and the second film F2 in the above-described manner every time the polishing table 3 makes one revolution, so that the processing system 49 can monitor the estimated film-thickness difference between the first film F1 and the second film F2 during polishing of the workpiece W.

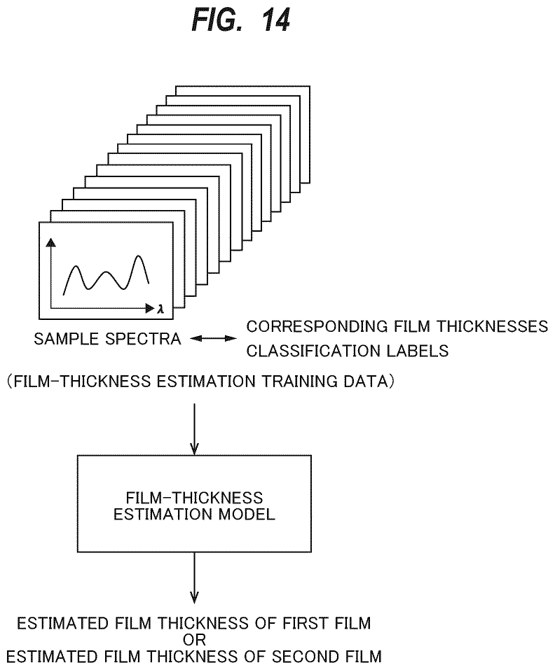

FIG. 14 is a diagram illustrating another embodiment of the producing of the film-thickness estimation model. Configurations and operations of this embodiment, which will not be particularly described, are the same as those of the embodiment described with reference to FIG. 10, and duplicated descriptions will be omitted. The film-thickness estimation model of this embodiment is a model for estimating both the film thickness of the first film F1 and the film thickness of the second film F2. The film-thickness estimation training data for use in the producing of the film-thickness estimation model of this embodiment includes, in addition to the multiple sample spectra and the film thicknesses corresponding to the multiple sample spectra, classification labels indicating groups to which the multiple sample spectra belong. The classification labels are obtained by performing clustering on the multiple sample spectra, as described with reference to FIG. 7. As shown in FIG. 14, the processing system 49 is configured to produce the film-thickness estimation model by performing machine learning using the film-thickness estimation training data including the multiple sample spectra, the film thicknesses corresponding to the multiple sample spectra, and the classification labels indicating the groups to which the multiple sample spectra belong.

The film-thickness estimation model is composed of a neural network. The memory 49a of the processing system 49 stores a program for producing the film-thickness estimation model according to the machine learning algorithm. The arithmetic device 49b of the processing system 49 produces the film-thickness estimation model by performing arithmetic operations according to instructions included in the program. Producing the film-thickness estimation model by machine learning involves optimizing parameters, such as the weights, of the neural network.

In the producing of the film-thickness estimation model, the multiple sample spectra and the classification labels indicating the groups to which the multiple sample spectra belong contained in the film-thickness estimation training data are used as explanatory variables, and the film thicknesses corresponding to the multiple sample spectra are used as objective variables (i.e., correct labels). The film-thickness estimation model is stored in the memory 49a of the processing system 49.

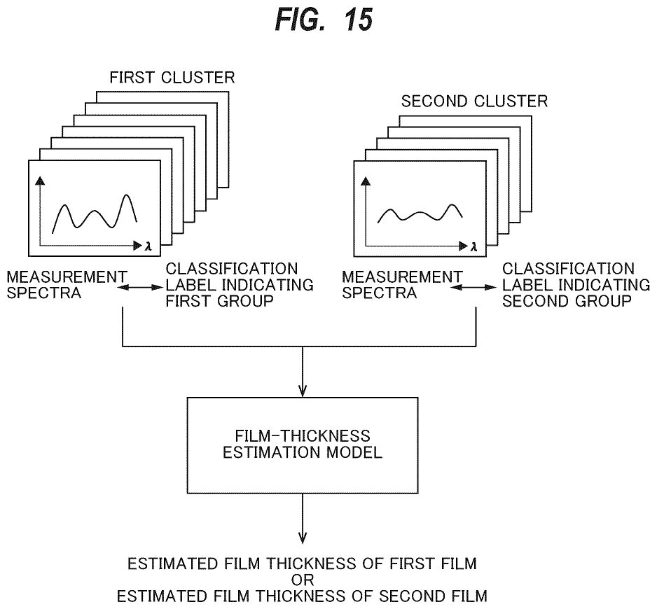

FIG. 15 is a diagram illustrating an embodiment of estimation of the film thicknesses of the first film F1 and the second film F2 of the workpiece W using the film-thickness estimation model shown in FIG. 14. Configurations and operations of this embodiment, which will not be particularly described, are the same as those of the embodiment described with reference to FIG. 12, and duplicated descriptions will be omitted. As shown in FIG. 15, the processing system 49 is configured to input the measurement spectrum of the reflected light from the first film F1 classified into the first group and a classification label indicating the first group into the trained film-thickness estimation model, and input the measurement spectrum of the reflected light from the second film F2 classified into the second group and a classification label indicating the second group into the film-thickness estimation model. The processing system 49 is configured to output, from the film-thickness estimation model, estimated film thicknesses of the first film F1 and the second film F2 of the workpiece W at the same polishing time.

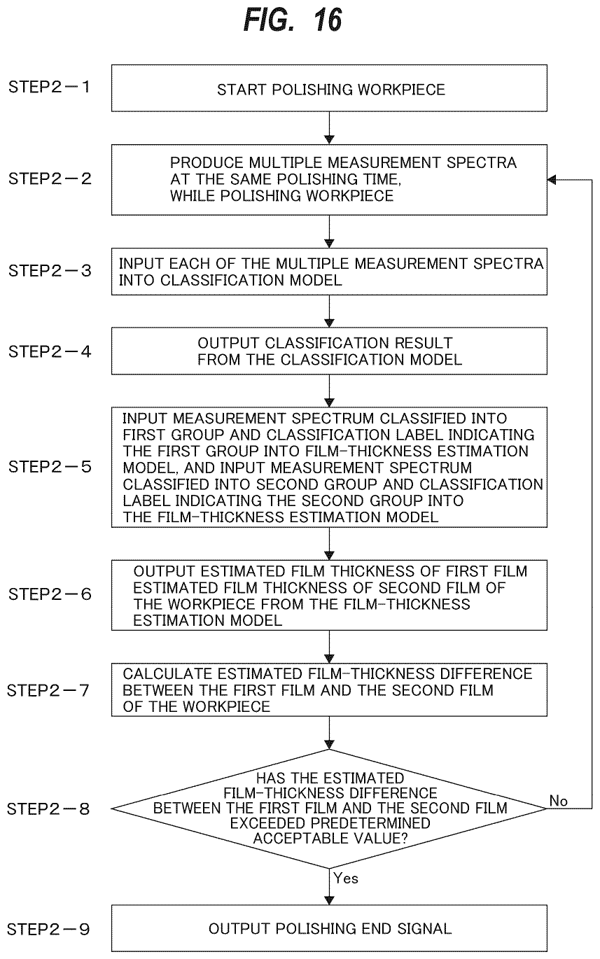

FIG. 16 is a flowchart showing an embodiment of a method of estimating the film-thickness difference between the first film and the second film during polishing of the workpiece W using the film-thickness estimation model shown in FIGS. 14 and 15.

Steps 2-1 to 2-4 of this embodiment are the same as the steps 1-1 to 1-4 of the flowchart shown in FIG. 13, and duplicated descriptions will be omitted.

In step 2-5, the processing system 49 inputs a measurement spectrum of reflected light from the first film F1 classified into the first group and a classification label indicating the first group into the film-thickness estimation model, and inputs a measurement spectrum of reflected light from the second film F2 classified into the second group and a classification label indicating the second group into the film-thickness estimation model (see FIG. 15). The film-thickness estimation model is a trained model constructed by machine learning using film-thickness estimation training data including multiple sample spectra, film thicknesses corresponding to the multiple sample spectra, and classification labels indicating groups to which the multiple sample spectra belong (see FIG. 14).

In step 2-6, the processing system 49 outputs an estimated film thickness of the first film F1 and an estimated film thickness of the second film F2 of the workpiece W at the same polishing time from the film-thickness estimation model (see FIG. 15).

Steps 2-7 to 2-9 in this embodiment are the same as the steps 1-7 to 1-9 in the flowchart shown in FIG. 13, and duplicated descriptions will be omitted.

During polishing of the workpiece W, a measurement point on the workpiece W measured by the optical film-thickness measuring apparatus 40 may be located at a boundary between the first film F1 and the second film F2 of the workpiece W. The film thicknesses of the first film F1 and the second film F2 may not be accurately estimated from a measurement spectrum of reflected light from the boundary between the first film F1 and the second film F2. Thus, in the embodiment described below, the processing system 49 is configured to exclude the measurement spectrum of the reflected light from the boundary between the first film F1 and the second film F2 in the estimation of the film thicknesses of the first film F1 and the second film F2.

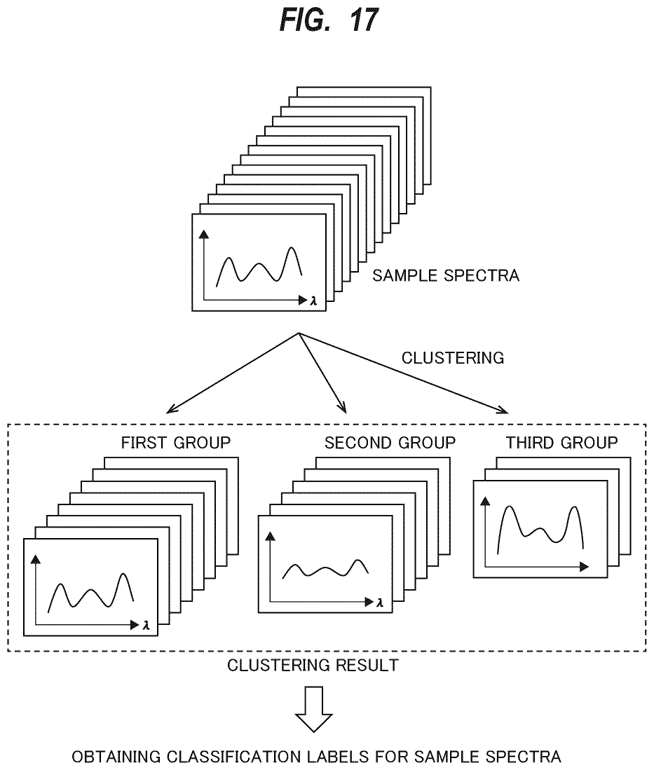

FIG. 17 is a diagram illustrating another embodiment of obtaining the classification labels for the multiple sample spectra for use in producing the classification model. Configurations and operations of this embodiment, which will not be particularly described, are the same as those of the embodiment described with reference to FIG. 7, and duplicated descriptions will be omitted. In this embodiment, the multiple sample spectra of the reflected light for use in producing of the classification model include a sample spectrum of reflected light from a boundary between the first film F1 and the second film F2 of the sample. The sample spectrum of the reflected light from the boundary between the first film F1 and the second film F2 of the sample has a different shape from the sample spectrum of the reflected light from the first film F1 and the sample spectrum of the reflected light from the second film F2.

As shown in FIG. 17, the processing system 49 is configured to perform clustering on the multiple sample spectra of the reflected light from the sample having the first film F1 and the second film F2 to classify the multiple sample spectra into a first group, a second group, and a third group. More specifically, the processing system 49 performs labeling for multiple groups, which are the clustering result of the clustering performed on the multiple sample spectra, as the first group to which the sample spectra of the reflected light from the first film F1 belong, the second group to which the sample spectra of the reflected light from the second film F2 belong, and the third group to which the sample spectra of the reflected light from the boundary between the first film F1 and the second film F2 belong.

The processing system 49 is configured to obtain classification labels indicating the groups to which the multiple sample spectra belong based on the clustering result. A classification label indicating the first group is associated with the sample spectra of the reflected light from the first film F1, a classification label indicating the second group is associated with the sample spectra of the reflected light from the second film F2, and a classification label indicating the third group is associated with the sample spectra of the reflected light from the boundary between the first film F1 and the second film F2. The classification labels associated with the sample spectra are stored in the arithmetic device 49b of the processing system 49.

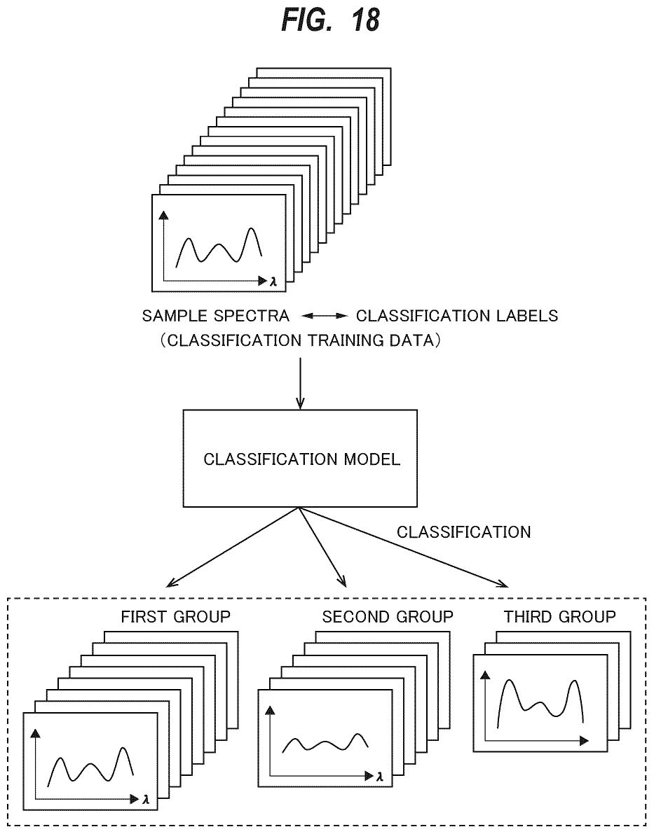

FIG. 18 is a diagram illustrating an embodiment of producing the classification model using classification training data including the classification labels shown in FIG. 17. Configurations and operations of this embodiment, which will not be particularly described, are the same as those of the embodiment described with reference to FIG. 8, and duplicated descriptions will be omitted. As shown in FIG. 18, the processing system 49 produces the classification model by performing machine learning using the classification training data including, in addition to the spectra of the reflected light from the first film F1 of the sample and the spectra of the reflected light from the second film F2, the sample spectra of the reflected light from the boundary between the first film F1 and the second film F2, and the classification labels for the multiple sample spectra.

The processing system 49 is configured to produce the film-thickness estimation model by performing machine learning using film-thickness estimation training data including the sample spectra belonging to the first group and the second group, obtained by excluding the sample spectra belonging to the third group from the multiple sample spectra, and film thicknesses corresponding to the sample spectra belonging to the first group and the second group, obtained by excluding the sample spectra belonging to the third group from the multiple sample spectra. The producing of the film-thickness estimation model using such film-thickness estimation training data can be applied to both producing of the first film-thickness estimation model and the second film-thickness estimation model described with reference to FIG. 10 and producing of the film-thickness estimation model described with reference to FIG. 14.

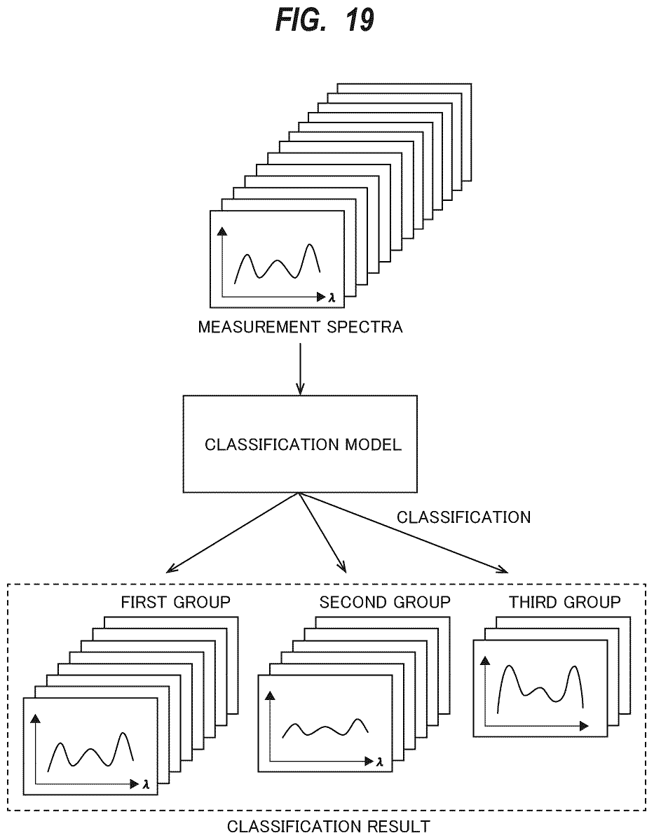

FIG. 19 is a diagram illustrating an embodiment of classification of the multiple measurement spectra using the classification model shown in FIG. 18. Configurations and operations of this embodiment, which will not be particularly described, are the same as those of the embodiment described with reference to FIG. 11, and duplicated descriptions will be omitted. As shown in FIG. 19, the processing system 49 is configured to input each of the multiple measurement spectra obtained at the same polishing time into the classification model that has been trained, and output, from the classification model, a classification result indicating that each of the multiple measurement spectra has been classified into either the first group, the second group, or the third group. The multiple measurement spectra produced during polishing of the workpiece W can be classified into the first group to which the measurement spectrum of the reflected light from the first film F1 belongs, the second group to which the measurement spectrum of the reflected light from the second film F2 belongs, and the third group to which the sample spectrum of the reflected light from the boundary between the first film F1 and the second film F2 belongs.

The processing system 49 is configured to input multiple measurement spectra belonging to the first group and the second group, obtained by excluding the measurement spectrum belonging to the third group from the multiple measurement spectra, into the film-thickness estimation model, and output estimated film thicknesses of the first film F1 and the second film F2 of the workpiece W at the same polishing time from the film-thickness estimation model. Such estimation of the film thicknesses of the first film F1 and the second film F2 can be applied to both the estimation of the film thicknesses of the first film F1 and the second film F2 using the first film-thickness estimation model and the second film-thickness estimation model described with reference to FIG. 12 and the estimation of the film thicknesses of the first film F1 and the second film F2 using the film-thickness estimation model described with reference to FIG. 15.

In the embodiment described with reference to FIGS. 17 to 19, in the step 1-4 of the flowchart shown in FIG. 13, the processing system 49 outputs, from the classification model, a classification result indicating that each of the multiple measurement spectra has been classified into either the first group, the second group, or the third group. Furthermore, in the step 1-5, the processing system 49 inputs the measurement spectrum belonging to the first group into the first film-thickness estimation model, and inputs the measurement spectrum belonging to the second group into the second film-thickness estimation model. The measurement spectrum belonging to the first group and the measurement spectrum belonging to the second group are obtained by excluding the measurement spectrum belonging to the third group from the multiple measurement spectra.

In the embodiment described with reference to FIGS. 17 to 19, in the step 2-4 of the flowchart shown in FIG. 16, the processing system 49 outputs, from the classification model, a classification result indicating that each of the multiple measurement spectra has been classified into either the first group, the second group, or the third group. Furthermore, in the step 2-5, the processing system 49 inputs the measurement spectrum belonging to the first group and the classification label indicating the first group into the film-thickness estimation model, and inputs the measurement spectrum belonging to the second group and the classification label indicating the second group into the film-thickness estimation model. The measurement spectrum belonging to the first group and the measurement spectrum belonging to the second group are obtained by excluding the measurement spectrum belonging to the third group from the multiple measurement spectra.

According to this embodiment, the measurement spectrum of the reflected light from the boundary between the first film F1 and the second film F2 of the workpiece W is excluded, so that the film thicknesses of the first film F1 and the second film F2 of the workpiece W can be accurately estimated by using the film-thickness estimation model.

In the above-described embodiments, the workpiece W has the first film F1 and the second film F2, while the workpiece W may have three or more (types of) films made of different materials. In this case, the processing system 49 produces a classification model that outputs a classification result indicating that spectra of reflected light from the three or more films of the workpiece W have been classified into three or more groups to which the spectra belong. In one embodiment, the processing system 49 may produce a classification model that outputs a classification result indicating that the spectra of the reflected light from the workpiece W have been classified into multiple groups that further include a group to which a spectrum of reflected light from a boundary between two adjacent films among the three or more films made of the different materials belongs in addition to the above-described three or more groups.

The previous description of embodiments is provided to enable a person skilled in the art to make and use the present invention. Moreover, various modifications to these embodiments will be readily apparent to those skilled in the art, and the generic principles and specific examples defined herein may be applied to other embodiments. Therefore, the present invention is not intended to be limited to the embodiments described herein but is to be accorded the widest scope as defined by limitation of the claims.

What is claimed is:

1. A film-thickness difference estimating method comprising:
producing multiple measurement spectra of reflected light from a workpiece at the same polishing time while polishing the workpiece, the workpiece having a first film and a second film made of different materials;
inputting each of the multiple measurement spectra into a classification model, the classification model being constructed as a trained model by machine learning using classification training data including multiple sample spectra of reflected light from a sample having the first film and the second film and classification labels for the multiple sample spectra;
outputting, from the classification model, a classification result indicating that each of the multiple measurement spectra has been classified into either a first group or a second group, the first group being a group to which a measurement spectrum of reflected light from the first film belongs, and the second group being a group to which a measurement spectrum of reflected light from the second film belongs;
inputting the measurement spectrum of the reflected light from the first film, which has been classified into the first group, and the measurement spectrum of the reflected light from the second film, which has been classified into the second group, into a film-thickness estimation model, the film-thickness estimation model being constructed as a trained model by machine learning using film-thickness estimation training data including the multiple sample spectra and film thicknesses corresponding to the multiple sample spectra;
outputting an estimated film thickness of the first film of the workpiece and an estimated film thickness of the second film of the workpiece at the polishing time from the film-thickness estimation model; and
calculating an estimated film-thickness difference between the first film and the second film of the workpiece at the polishing time by subtracting the estimated film thickness of the second film from the estimated film thickness of the first film.

2. The film-thickness difference estimating method according to claim 1, wherein
inputting the measurement spectrum classified into the first group and the measurement spectrum classified into the second group into the film-thickness estimation model comprises inputting the measurement spectrum classified into the first group into a first film-thickness estimation model, and inputting the measurement spectrum classified into the second group into a second film-thickness estimation model,
the first film-thickness estimation model is constructed as a trained model by machine learning using first film-thickness estimation training data including sample spectra belonging to the first group among the multiple sample spectra and film thicknesses corresponding to the sample spectra belonging to the first group,
the second film-thickness estimation model is constructed as a trained model by machine learning using second film-thickness estimation training data including sample spectra belonging to the second group among the multiple sample spectra and film thicknesses corresponding to the sample spectra belonging to the second group, and
outputting the estimated film thickness of the first film of the workpiece and the estimated film thickness of the second film of the workpiece at the polishing time from the film-thickness estimation model comprises outputting the estimated film thickness of the first film of the workpiece at the polishing time from the first film-thickness estimation model, and outputting the estimated film thickness of the second film of the workpiece at the polishing time from the second film-thickness estimation model.

3. The film-thickness difference estimating method according to claim 1, wherein
the film-thickness estimation training data further includes classification labels indicating groups to which the multiple sample spectra belong, and
inputting the measurement spectrum classified into the first group and the measurement spectrum classified into the second group into the film-thickness estimation model comprises inputting the measurement spectrum classified into the first group and a classification label indicating the first group into the film-thickness estimation model, and inputting the measurement spectrum classified into the second group and a classification label indicating the second group into the film-thickness estimation model.

4. The film-thickness difference estimating method according to claim 1, wherein the classification labels for the multiple sample spectra are obtained by performing clustering on the multiple sample spectra to classify the multiple sample spectra into the first group and the second group.

5. The film-thickness difference estimating method according to claim 1, wherein
the multiple sample spectra include a sample spectrum of reflected light from a boundary between the first film and the second film of the sample,
outputting the classification result indicating that each of the multiple measurement spectra has been classified into either the first group or the second group from the classification model comprises outputting a classification result indicating that each of the multiple measurement spectra has been classified into either the first group, the second group, or a third group from the classification model, the third group being a group to which a measurement spectrum of reflected light from a boundary between the first film and the second film is classified, and
the film-thickness estimation training data includes sample spectra excluding a sample spectrum belonging to the third group from the multiple sample spectra, and film thicknesses corresponding to the sample spectra excluding the sample spectrum belonging to the third group from the multiple sample spectra.

6. The film-thickness difference estimating method according to claim 5, wherein the classification labels for the multiple sample spectra are obtained by performing clustering on the multiple sample spectra to classify the multiple sample spectra into the first group, the second group, and the third group.

7. The film-thickness difference estimating method according to claim 1, wherein
the first film comprises a dielectric film,
the second film comprises a metal film, and
the film-thickness difference estimating method further comprises:
outputting a polishing end signal to terminate polishing of the workpiece when the estimated film-thickness difference exceeds a predetermined acceptable value.

8. The film-thickness difference estimating method according to claim 1, wherein
the first film comprises a metal film,
the second film comprises a dielectric film, and
the film-thickness difference estimating method further comprises:
outputting a polishing continuation signal to continue polishing of the workpiece when the estimated film-thickness difference is equal to or larger than a predetermined threshold value and after a polishing end point of the workpiece.

9. An optical film-thickness measuring apparatus comprising:
a light source configured to emit light;
an optical sensor head configured to direct the light emitted from the light source to a workpiece and receive reflected light from the workpiece, the workpiece having a first film and a second film made of different materials; and
a processing system configured to produce a spectrum of the reflected light,
wherein the processing system is configured to:
produce multiple measurement spectra of reflected light from a workpiece at the same polishing time during polishing of the workpiece;
input each of the multiple measurement spectra into a classification model, the classification model being constructed as a trained model by machine learning using classification training data including multiple sample spectra of reflected light from a sample having the first film and the second film and classification labels for the multiple sample spectra;
output, from the classification model, a classification result indicating that each of the multiple measurement spectra has been classified into either a first group or a second group, the first group being a group to which a measurement spectrum of reflected light from the first film belongs, and the second group being a group to which a measurement spectrum of reflected light from the second film belongs;
input the measurement spectrum of the reflected light from the first film, which has been classified into the first group, and the measurement spectrum of the reflected light from the second film, which has been classified into the second group, into a film-thickness estimation model, the film-thickness estimation model being constructed as a trained model by machine learning using film-thickness estimation training data including the multiple sample spectra and film thicknesses corresponding to the multiple sample spectra;
output an estimated film thickness of the first film of the workpiece and an estimated film thickness of the second film of the workpiece at the polishing time from the film-thickness estimation model; and
calculate an estimated film-thickness difference between the first film and the second film of the workpiece at the polishing time by subtracting the estimated film thickness of the second film from the estimated film thickness of the first film.

10. The optical film-thickness measuring apparatus according to claim 9, wherein
the processing system is configured to:
input the measurement spectrum classified into the first group into a first film-thickness estimation model, and input the measurement spectrum classified into the second group into a second film-thickness estimation model; and
output the estimated film thickness of the first film of the workpiece at the polishing time from the first film-thickness estimation model, and output the estimated film thickness of the second film of the workpiece at the polishing time from the second film-thickness estimation model,
the first film-thickness estimation model is constructed as a trained model by machine learning using first film-thickness estimation training data including sample spectra belonging to the first group among the multiple sample spectra and film thicknesses corresponding to the sample spectra belonging to the first group, and
the second film-thickness estimation model is constructed as a trained model by machine learning using second film-thickness estimation training data including sample spectra belonging to the second group among the multiple sample spectra and film thicknesses corresponding to the sample spectra belonging to the second group.

11. The optical film-thickness measuring apparatus according to claim 9, wherein
the film-thickness estimation training data further includes classification labels indicating groups to which the multiple sample spectra belong, and
the processing system is configured to input the measurement spectrum classified into the first group and a classification label indicating the first group into the film-thickness estimation model, and input the measurement spectrum classified into the second group and a classification label indicating the second group into the film-thickness estimation model.

12. The optical film-thickness measuring apparatus according to claim 9, wherein the classification labels for the multiple sample spectra are obtained by performing clustering on the multiple sample spectra to classify the multiple sample spectra into the first group and the second group.

13. The optical film-thickness measuring apparatus according to claim 9, wherein
the multiple sample spectra include a sample spectrum of reflected light from a boundary between the first film and the second film of the sample,
the processing system is configured to output a classification result indicating that each of the multiple measurement spectra has been classified into either the first group, the second group, or a third group from the classification model, the third group being a group to which a measurement spectrum of reflected light from a boundary between the first film and the second film is classified, and
the film-thickness estimation training data includes sample spectra excluding a sample spectrum belonging to the third group from the multiple sample spectra, and film thicknesses corresponding to the sample spectra excluding the sample spectrum belonging to the third group from the multiple sample spectra.

14. The optical film-thickness measuring apparatus according to claim 13, wherein the classification labels for the multiple sample spectra are obtained by performing clustering on the multiple sample spectra to classify the multiple sample spectra into the first group, the second group, and the third group.

15. The optical film-thickness measuring apparatus according to claim 9, wherein
the first film comprises a dielectric film,
the second film comprises a metal film, and
the processing system is configured to output a polishing end signal to terminate polishing of the workpiece when the estimated film-thickness difference exceeds a predetermined acceptable value.

16. The optical film-thickness measuring apparatus according to claim 9, wherein
the first film comprises a metal film,
the second film comprises a dielectric film, and
the processing system is configured to output a polishing continuation signal to continue polishing of the workpiece when the estimated film-thickness difference is equal to or larger than a predetermined threshold value and after a polishing end point of the workpiece.
